(19) United States
(12) Patent Application Publication
(10) Pub. No.: US 2025/0104797 A1
(43) Pub. Date: Mar. 27, 2025

(54) MEMORY ISOLATION TO IMPROVE SYSTEM RELIABILITY

(71) Applicant: Intel Corporation, Santa Clara, CA (US)

(72) Inventors: Zhiguo Wei, Shanghai (CN); Du Lin, Shanghai (CN); Tao Xu, Shanghai (CN); Yufu Li, Portland, OR (US); Zhenfu Chai, Shanghai (CN)

(73) Assignee: Intel Corporation, Santa Clara, CA (US)

(21) Appl. No.: 18/970,293

(22) Filed: Dec. 5, 2024

Related U.S. Application Data
(63) Continuation-in-part of application No. PCT/CN2024/088723, filed on Apr. 18, 2024.

(30) Foreign Application Priority Data
Apr. 19, 2024 (WO) PCT/CN2024/088723

(51) Int. Cl. G11C 29/00; G11C 29/52

(52) U.S. Cl. CPC G11C 29/76; G11C 29/52; G11C 29/789

(57) ABSTRACT

Example systems, apparatus, articles of manufacture, and methods that perform memory preservation to improve system reliability are disclosed. Example apparatus disclosed herein increment an error count after detection of an error associated with a memory cell. Example apparatus also isolate a system memory address of the memory cell based on the error count.

### RELATED APPLICATION(S)

This patent claims the benefit of International Patent Application No. PCT/CN2024/088723, which was filed on Apr. 19, 2024. International Patent Application No. PCT/CN2024/088723 is hereby incorporated herein by reference in its entirety. Priority to International Patent Application No. PCT/CN2024/088723 is hereby claimed.

### BACKGROUND

Processor-based systems, such as servers, personal computers, tablets, smartphones, etc., include memory to store instructions and/or data. The memory in such systems may include memory cells arranged into rows of memory, which may be further arranged into banks of memory and/or other larger memory groupings. In some processor-based systems, an error associated with a single memory cell may result in the system disabling an entire rank or other grouping of memory that includes that single memory cell. Disabling an entire memory rank/grouping due to failure of a single memory cell can degrade system reliability, especially over time as the number of failed memory cells increases.

### BRIEF DESCRIPTION OF THE DRAWINGS

FIG. 1 is a block diagram of an example system including example memory isolation circuitry that performs memory cell isolation to improve system reliability in accordance with teachings of this disclosure.

FIG. 2 is a block diagram of an example memory subsystem included in the system of FIG. 1.

FIG. 3 is a block diagram of an example memory module included in the memory subsystem of FIG. 2.

FIG. 4 is a block diagram of example address translation circuitry included in the system of FIG. 1.

FIG. 5 illustrates example memory errors that are correctable by the memory subsystem of FIGS. 1 and/or 2.

FIG. 6 is a block diagram of example memory repair circuitry included in the system of FIG. 1.

FIG. 7 is a block diagram of an example implementation of the memory isolation circuitry of FIG. 1.

FIGS. 8-9 illustrate example information utilized by the memory isolation circuitry of FIGS. 1 and/or 7 to perform memory cell isolation.

FIG. 10 illustrates example operation of the memory isolation circuitry of FIGS. 1 and/or 7 to perform memory cell isolation.

FIG. 11 is a flowchart representative of example machine readable instructions and/or example operations that may be executed, instantiated, and/or performed by example programmable circuitry to implement the memory isolation circuitry of FIG. 7.

FIG. 12 is a block diagram of an example processing platform including programmable circuitry structured to execute, instantiate, and/or perform the example machine readable instructions and/or perform the example operations of FIG. 11 to implement the memory isolation circuitry of FIG. 7.

FIG. 13 is a block diagram of an example implementation of the programmable circuitry of FIG. 12.

FIG. 14 is a block diagram of another example implementation of the programmable circuitry of FIG. 12.

FIG. 15 is a block diagram of an example software/firmware/instructions distribution platform (e.g., one or more servers) to distribute software, instructions, and/or firmware (e.g., corresponding to the example machine readable instructions of FIG. 11) to client devices associated with end users and/or consumers (e.g., for license, sale, and/or use), retailers (e.g., for sale, re-sale, license, and/or sub-license), and/or original equipment manufacturers (OEMs) (e.g., for inclusion in products to be distributed to, for example, retailers and/or to other end users such as direct buy customers).

In general, the same reference numbers will be used throughout the drawing(s) and accompanying written description to refer to the same or like parts. The figures are not necessarily to scale.

### DETAILED DESCRIPTION

As described above, some processor-based systems, such as servers, personal computers, tablets, smartphones, etc., disable an entire rank or other grouping of memory in the event of an error occurring in a single memory cell of that memory rank/grouping. Over time, such an approach for responding to memory cell errors can reduce, potentially substantially, the amount of available system memory, which may degrade system performance and reliability. To help mitigate such behavior, some systems implement memory repair features, such as a post package repair (PPR) feature, that attempt to repair a memory cell error by replacing a row of memory including a memory cell exhibiting an error with another, redundant row of memory held in reserve.

However, such memory repair features may exhibit one or more limitations. For example, the PPR features implemented by some systems may have a limited set of resources, such as a limited number of redundant/reserved rows of memory, that can be used to repair rows of memory including memory cells exhibiting errors, also referred to herein as failing memory cells, failed memory cells, etc. In such systems, after the PPR resources (e.g., the redundant/reserved rows of memory) are exhausted, the system defaults to again disabling entire memory ranks/groupings in the event of an error occurring in a single memory cell of those memory ranks/groupings. Thus, such systems may provide a limited ability to delay system reliability and/or performance degradation due to memory cell failures over time.

Also, some systems may include memory subsystems that implement error checking and correcting (ECC) and, thus, are able to correct some memory errors, referred to herein as correctable errors, correctable memory errors, etc. However, the PPR features implemented by some such systems may be unable to distinguish between correctable errors and uncorrectable errors. As such, those systems may waste the limited PPR resources (e.g., the redundant/reserved rows of memory) by using those resources to replace rows of memory having correctable memory errors, rather than limiting the use of PPR resources to replacing rows of memory having uncorrectable memory errors.

In contrast, example memory isolation techniques disclosed herein can be employed by systems to isolate system memory addresses associated with memory cell errors, thereby preventing system access to those failed memory cells. As a result, systems employing such memory isolation techniques can keep a memory rank or other memory grouping enabled even in the face of errors associated with memory cells in that rank/grouping. Furthermore, some example memory isolation techniques disclosed herein can limit the use of PPR resources to replacing rows of memory having uncorrectable memory errors, with rows of memory having correctable memory errors being isolated rather than replaced (e.g., until an error limit is reached). Also, some example memory isolation techniques disclosed herein can utilize memory isolation to protect the system against memory cell errors (e.g., correctable and uncorrectable) after the PPR resources have been exhausted, thereby avoiding the need to disable the memory ranks/groupings including the memory cell errors. Furthermore, example memory isolation techniques disclosed herein can be used in systems that do not support PPR or similar repair features to protect those system against memory cell errors even though the failing memory is unable to be repaired. Thus, in the face of memory cell errors, example memory isolation techniques disclosed herein are able to improve system performance and/or reliability relative to other systems that do not employ such techniques.

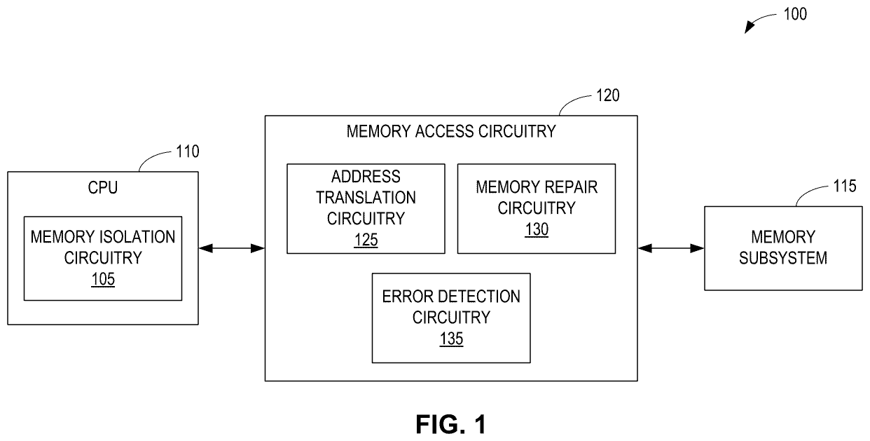

FIG. 1 is a block diagram of an example system 100 including example memory isolation circuitry 105 that performs memory cell isolation in accordance with teachings of this disclosure. The example system 100 of FIG. 1 includes an example processor 110, an example memory subsystem 115, and example memory access circuitry 120. In the illustrated example of FIG. 1, the memory access circuitry 120 includes example address translation circuitry 125, example memory repair circuitry 130 and example error detection circuitry 135. However, in some examples, the memory subsystem 115 and/or the processor 110 may implement one or more of the address translation circuitry 125, the memory repair circuitry 130 and/or the error detection circuitry 135. Also, in some examples, one or more of the address translation circuitry 125, the memory repair circuitry 130 and/or the error detection circuitry 135 may be implemented by circuitry other than the processor 110, the memory subsystem 115 and/or the memory access circuitry 120.

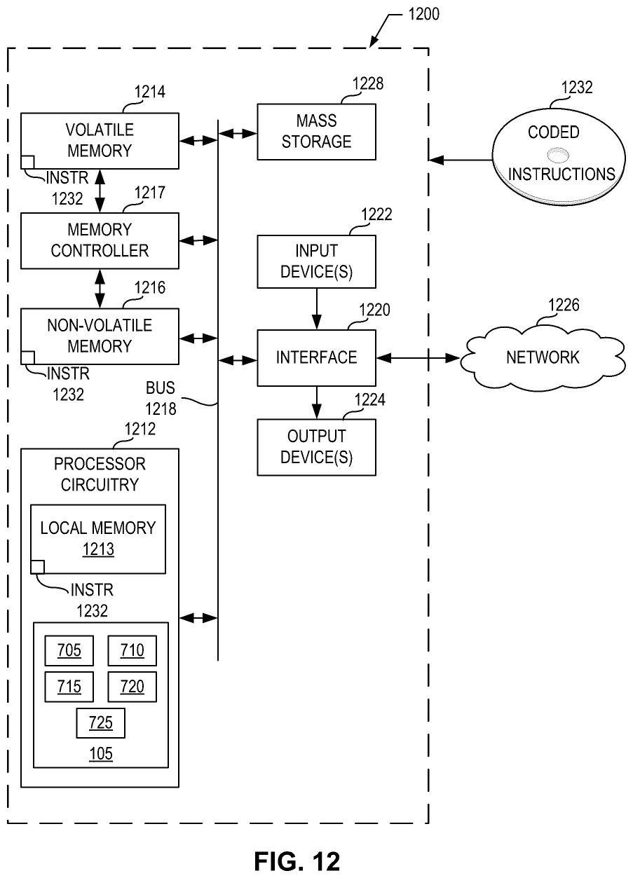

In the illustrated example, the processor 110 can be implemented by any type(s) and/or number processor circuits, programmable circuitry, etc., such as one or more central processing units (CPUs), graphics processing units (GPUs), network processing units (NPUs), microprocessors, microcontrollers, etc. For example, the processor 110 can be implemented by the programmable circuitry 1212 in the programmable circuitry platform 1200 of FIG. 12. As shown in the example of FIG. 1, the processor 110 includes and/or otherwise implements the memory isolation circuitry 105.

In the illustrated example, the memory isolation circuitry 105 isolates system memory addresses associated with memory cell errors in the memory subsystem 115, thereby preventing system access to those failed memory cells. Thus, the memory isolation circuitry 105 permits memory ranks and/or other memory groupings of the memory subsystem 115 that are associated with memory cell error to remain enabled. As a result, other memory cells of those memory ranks and/or other memory groupings remain accessible to the system 100.

Furthermore, in some examples, the memory isolation circuitry 105 limits the use of PPR resources (e.g., managed by the memory repair circuitry 130, as disclosed in further detail below) to replacing rows of memory in the memory subsystem 115 that have uncorrectable memory errors, with rows of memory having correctable memory errors being isolated rather than replaced (e.g., until an error limit is reached). Also, in some examples, the memory isolation circuitry 105 utilizes memory isolation to protect the system 100 against memory cell errors (e.g., correctable and uncorrectable) after the PPR resources (e.g., managed by the memory repair circuitry 130, as disclosed in further detail below) have been exhausted, thereby avoiding the need to disable the memory ranks/groupings of the memory subsystem 115 including the memory cell errors. As disclosed in further detail below, the memory isolation circuitry 105 utilizes the address translation circuitry 125, the memory repair circuitry 130 and the error detection circuitry 135 to perform the foregoing operations.

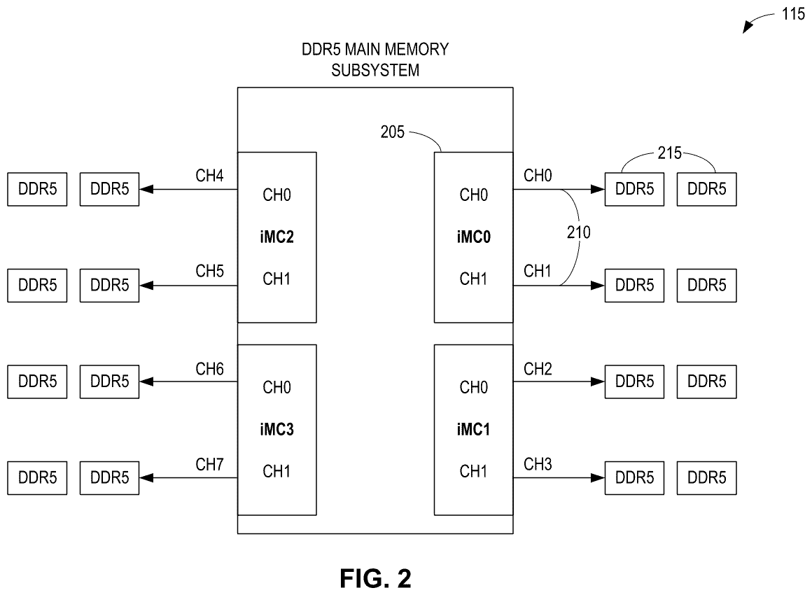

FIG. 2 is a block diagram of the example memory subsystem 115 included in the system 100 of FIG. 1. The memory subsystem 115 of FIG. 2 corresponds to an example double data rate 5 (DDR5) memory subsystem 115 used to control and access one or more memory devices. In the illustrated example, the DDR5 memory subsystem 115 includes four (4) example DDR5 integrated memory controllers (iMC) 205 with two (2) example DDR5 channels 210 per iMC. Furthermore, in the illustrated example, there are two (2) example DDR5 dual in-line memory modules (DIMMs) 215 populated on each channel 210.

In the illustrated example, each DIMM 215 includes up to two (2) DDR5 ranks. A rank includes enough dynamic random access memory (DRAM) devices to drive the full width of the corresponding channel 210. For example, in a DIMM 215 corresponding to an x4 registered DIMM (RDIMM), a rank may include twenty (20) DRAM devices.

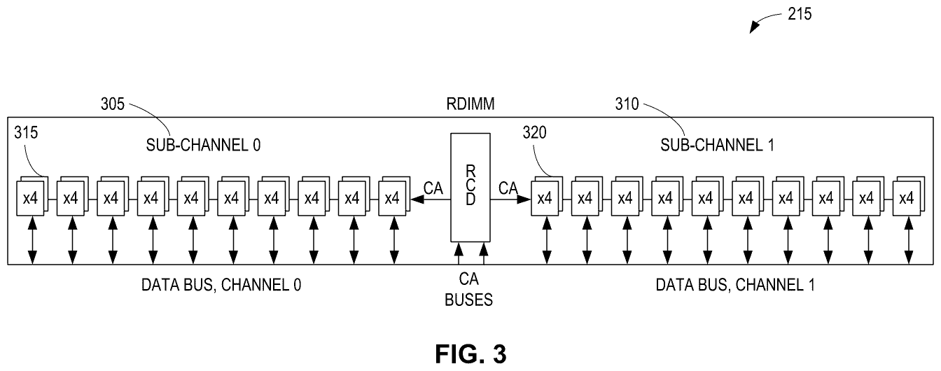

FIG. 3 is a block diagram of an example implementation of one of the DIMMs 215 included in the memory subsystem 115 of FIG. 2. The example DIMM 215 of FIG. 3 corresponds to an example x4 RDIMM 215. The RDIMM 215 has one rank with two (2) example sub channels 305 and 310, which are referred to as sub-channel 0 and sub-channel 1 in FIG. 3. In the illustrated example, the sub-channel 305 includes ten (10) example x4 DRAM devices 315 and the sub-channel 310 includes ten (10) example x4 DRAM devices 320. Each DRAM device 315 and 320 is referred to as a nibble. In the illustrated example, each DRAM device 315 and 320 includes dozens of memory banks, with each bank including thousands of rows of memory (e.g., memory cells). In some examples, a read command from the processor 110 (e.g., CPU) reads out one row (e.g., one cache line of 64 bytes) from the memory subsystem 115.

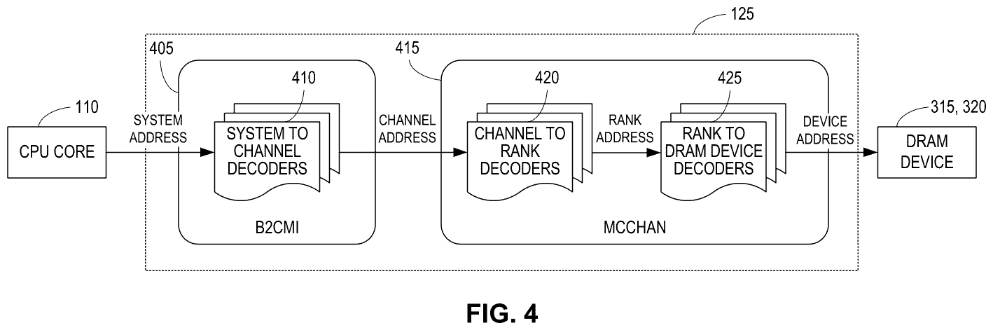

FIG. 4 is a block diagram of the example address translation circuitry 125 included in the system 100 of FIG. 1. In the example system 100 of FIG. 1, system DRAM of the memory subsystem 115 is arranged as a contiguous block of coherent memory made up of the multiple interleaved DRAM devices 315 and 320. The system DRAM is made accessible to the processor 110 (and other elements of the system 100) as a system-scoped memory address space is formed by system addresses used to access memory cells of the DRAM devices 315 and 320. The memory cells of the memory subsystem 115 are physically accessed via a device-scoped memory address space formed by device addresses that are based on combination of physical identification information, such as <Socket, Memory Controller, Channel, DIMM, Rank, Sub Channel, DRAM, Bank, Row, Column>. In the illustrated example, corresponding system addresses and device addresses have a 1-to-1 mapping that is based on an interleaving mechanism, such as a bijection function, which means a given memory cell in a given DRAM device 315 and 320 of the memory subsystem 115 can be located using a unique system address and a unique device address.

In the illustrated example, software executing on the processor 110 (e.g., CPU host-side software, such as an operating system (OS)), uses a system address to access the memory cell of a given DRAM device 315, 320 of the memory subsystem 115. The memory access request is routed to an example bridge to converged memory interface (B2CMI) 405 included in the address translation circuitry 125. The B2CMI 405 includes example B2CMI decoders 410 that translate the system address to a corresponding channel address interleaving information programmed in B2CMI decoders 410. Subsequently, the decoded channel address is routed to an example memory channel decoder 415 included in the address translation circuitry 125. The memory channel decoder circuitry 415 includes example rank decoders 420 to translate the channel address to a corresponding rank address using the interleaving information. The memory channel decoder 415 also includes example device decoders 425 to decode the rank address to a corresponding device address based on the interleaving information. A memory access transaction is then sent to the appropriate DRAM device 315, 320 using the device address to access the memory cell in question using appropriate DDR5 commands. As described above, although the address translation circuitry 125 is illustrated in FIG. 1 as being implemented in the memory access circuitry 120, in some examples, some or all of the address translation circuitry 125 (e.g., the B2CMI 405 and/or the memory channel decoder circuitry 415 can be implemented in the memory subsystem 115 (e.g., in one or more of the iMCs 205), in the processor 110 and/or in circuitry other than the processor 110, the memory subsystem 115 and/or the memory access circuitry 120.

Returning to FIGS. 1 and 2, in some examples, the memory subsystem 115 implements one or more error checking and correcting (ECC) algorithms that can detect and correct one or more possible error patterns in data returned by the memory cells of the memory subsystem 115. For example, the ECC algorithm(s) can be implemented by one or more of the iMCs 205, by circuitry other than the iMCs 205 in the memory subsystem 115, etc., or any combination thereof. As used herein, a memory error pattern that can be detected and corrected by a particular ECC algorithm is referred to as a correctable error (CE). Conversely, a memory error pattern that is undetectable or uncorrectable by the available ECC algorithm(s) is referred to as an uncorrectable error (UCE).

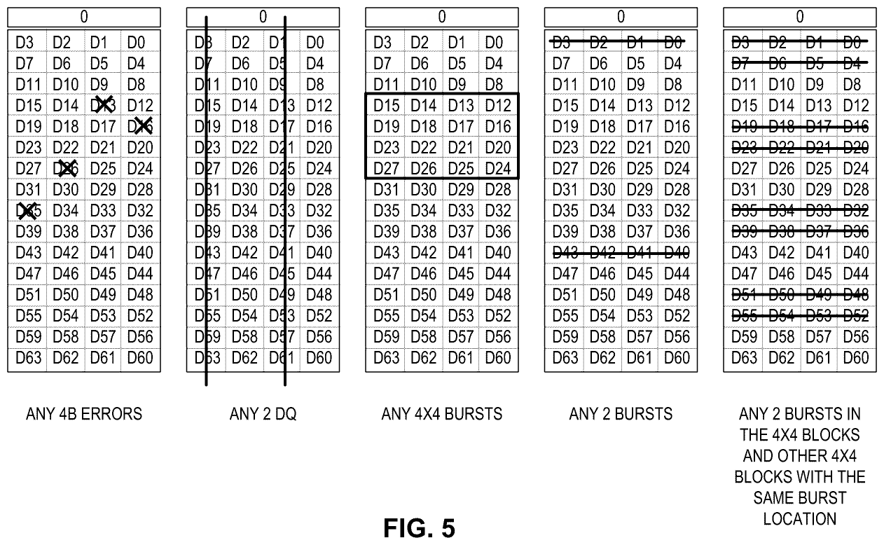

FIG. 5 illustrates example memory error patterns 500 that are correctable by the memory subsystem 115 of FIGS. 1 and/or 2. The correctable error patterns 500 illustrated in FIG. 5 include error patterns that are correctable by a DDR5 ECC single device data correction (SDDC) algorithm in an x4 DRAM nibble. In some examples, other error patterns not illustrated in FIG. 5 are uncorrectable errors.

Returning to FIGS. 1-2, in some examples, the memory subsystem 115 (e.g., one or more of the iMCs 205 and/or other circuitry) reports detected memory cell errors to the processor 110, including information identifying whether a given detected memory cell error is correctable or uncorrectable. For example, the memory subsystem 115 may report a device address of a memory cell associated with an error, and an indicator or whether the error is correctable or uncorrectable. In some examples, the processor 110 implements one or more algorithms to trace memory errors based on the reported device address of the associated memory cell. For example, the processor 110 may include circuitry and/or execute software to implement one or more of a reliability, availability and serviceability (RAS) algorithm, an advanced memory test (AMT) algorithm, etc., that traces memory errors using memory cell device addresses. In some examples, a built-in operating system (BIOS) of the processor 110 implements the reverse operations of the address translation circuitry 125 described above to translate the device address of a memory cell associated with a detected error back to the corresponding system address of the memory cell. For example, the BIOS of the processor 110 can perform such device address to system address translation based on the same memory interleaving information used by the address translation circuitry 125 to perform system address to device address translation. In some examples, the BIOS of the processor 110 then reports the system address of the memory cell associated with the detected error to the operating system (OS) of the processor 110.

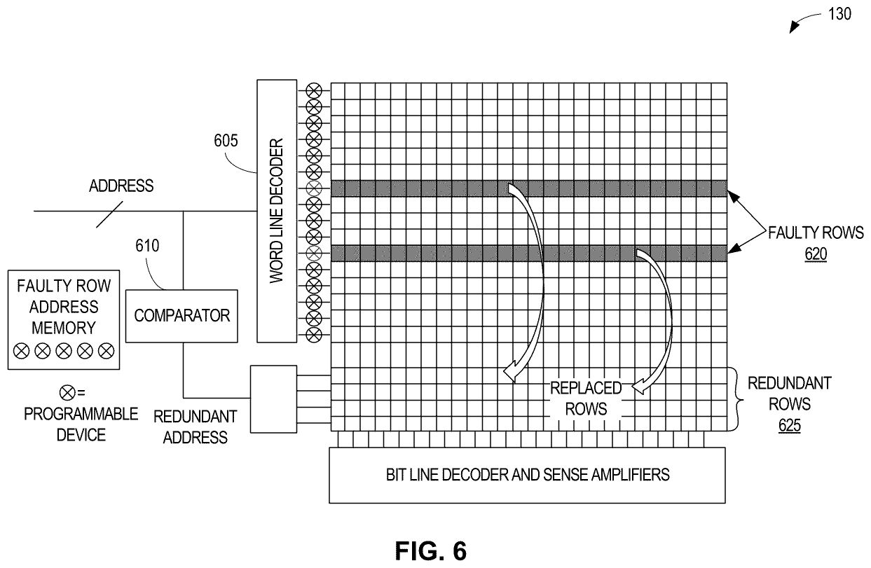

FIG. 6 is a block diagram of the example memory repair circuitry 130 included in the system 100 of FIG. 1. Because uncorrectable memory errors can cause fatal system crashes, the system 100 of FIG. 1 includes the memory repair circuitry 130 to repair failing rows of memory in the memory subsystem 115 that includes a memory cell exhibiting uncorrectable memory errors. In the illustrated example of FIG. 6, the memory repair circuitry 130 implements an example post package repair (PPR) algorithm to repair a failing row of memory that includes a memory cell associated with detected uncorrectable memory.

PPR is a DRAM row repairing algorithm which includes an example comparator 605 and an example word line decoder 610 that replace failing rows of memory (e.g., example memory rows 620) in the memory subsystem 115 with reserved, redundant rows of memory (e.g., example redundant memory rows 625) after the memory subsystem 115 has been packaged. PPR operates to improve memory reliability and availability in the field. However, the number of PPR redundant rows of memory 625 is finite. For example, in the memory repair circuitry 130 of FIG. 6, there are just four (4) redundant rows of memory 625 per DRAM bank group. Thus, when all the redundant rows 625 have been used, there are no more redundant memory rows 625 available to repair new failing memory rows of that DRAM bank group.

Thus, the PPR resources available for a given DRAM bank group may be limited. As a result, the limited PPR resources can be exhausted if several uncorrectable errors continue to happen in the same bank group. After that point, further uncorrectable errors in that memory bank group cannot be repaired due to the lack of available PPR resources, which can reduce system reliability.

In other systems that do not include the memory isolation circuitry 105 or that otherwise do not employ memory isolation as disclosed herein, after the PPR resources a given DRAM bank group are exhausted and a subsequent uncorrectable error is detected for a memory cell in that bank group, the BIOS may disable the whole DDR rank including that DRAM bank group to isolate the failed memory from system to avoid a system crash. This is a waste of memory resources, because any subsequent error can cause an entire DDR rank to be disabled (with the loss of an entire rank resulting in the loss of several Gigabytes of memory, in some examples). Also, in systems that utilize symmetric memory channel configuration, if one rank is disabled on one memory channel, the BIOS has to disable the same rank on other channels. This can result in a substantial reduction in the available system memory size. Furthermore, for high bandwidth memory (HBM), the BIOS may disable the entire HBM memory to isolate the uncorrectable error after the PPR resources are exhausted for a given DRAM bank group, which may result in return of the package containing the HBM memory from the end-user.

Also, other systems that do not include the memory isolation circuitry 105 or that otherwise do not employ memory isolation as disclosed herein, may not distinguish between uncorrectable memory errors and correctable memory errors. Thus, in such other system, when the BIOS of such a systems detects the memory cell error, the BIOS invokes the PPR feature to repair the failing row without distinguishing whether the error is uncorrectable or correctable. As a result, the limited PPR resources of a DRAM bank group may be exhausted by correctable errors, leaving subsequent uncorrectable errors unable to be fixed due to a lack of available PPR resources.

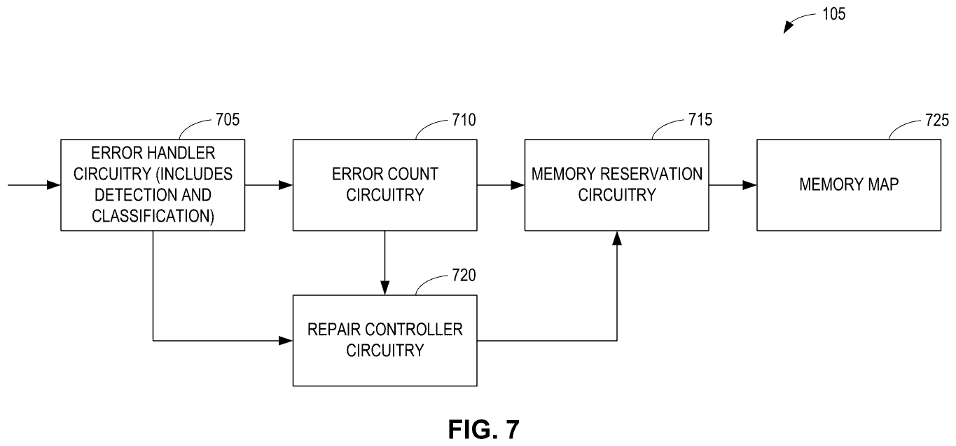

FIG. 7 is a block diagram of an example implementation of the memory isolation circuitry 105 of FIG. 1. The memory isolation circuitry 105 of FIG. 7 may be instantiated (e.g., creating an instance of, bring into being for any length of time, materialize, implement, etc.) by programmable circuitry such as a Central Processor Unit (CPU) executing first instructions. Additionally or alternatively, the memory isolation circuitry 105 of FIG. 7 may be instantiated (e.g., creating an instance of, bring into being for any length of time, materialize, implement, etc.) by (i) an Application Specific Integrated Circuit (ASIC) and/or (ii) a Field Programmable Gate Array (FPGA) structured and/or configured in response to execution of second instructions to perform operations corresponding to the first instructions. It should be understood that some or all of the circuitry of FIG. 7 may, thus, be instantiated at the same or different times. Some or all of the circuitry of FIG. 7 may be instantiated, for example, in one or more threads executing concurrently on hardware and/or in series on hardware. Moreover, in some examples, some or all of the circuitry of FIG. 7 may be implemented by microprocessor circuitry executing instructions and/or FPGA circuitry performing operations to implement one or more virtual machines and/or containers. For example, some or all of the circuitry of FIG. 7 may be implemented by a BIOS executed by the processor 110 (e.g., such as by a PPR handler included in the BIOS).

The example memory isolation circuitry 105 of FIG. 7 includes example error handler circuitry 705, example error count circuitry 710, example memory preservation circuitry 715, example repair controller circuitry 720 and an example memory map 725. The error handler circuitry 705 of the illustrated example accesses the detected memory cell errors reported by the memory subsystem 115, as described above. The error handler circuitry 705 also classifies a reported memory cell error as correctable or uncorrectable based on the information provided by the memory subsystem 115, as described above. Furthermore, depending on the type and/or severity of the error, the error handler circuitry 705 translates the device address of a memory cell associated with a detected error to the corresponding system address of that memory cell, as described above.

The error count circuitry 710 of the illustrated example increments an error count associated with a memory cell after detection of an error associated with that memory cell by the error handler circuitry 705. In some examples, the error count is a count of correctable errors associated with a row of memory including that memory cell. Thus, in some such examples, a detected error associated with any memory cell in that row causes the error count circuitry 710 to increment the error count associated with that row of memory. In some examples, the error count circuitry 710 causes the error handler circuitry 705 to translate the device address of the memory cell associated with the error to the corresponding system address of the memory cell after a determination that the error count is within an error limit or does not satisfy (e.g., is less than, is less than or equal to, etc.) an error limit threshold.

The memory preservation circuitry 715 of the illustrated example determines whether to isolate a system memory address of a memory cell (or, in other words, isolate the memory cell) after detection of an error associated with that memory cell. In the illustrated example, the memory preservation circuitry 715 determines whether to isolate the memory cell based on the error count associated with that memory cell, which may be the error account associated with the row of memory including that memory cell, as described above. In some examples, the memory preservation circuitry 715 isolates a given memory cell by reserving (e.g., marking) the system memory address of the memory as unusable in the memory map 725. In some examples, the memory preservation circuitry 715 isolates a given memory cell by reserving (e.g., marking) a range of system memory addresses as unusable in the memory map 725, with the range of system addresses including the system memory address of the memory cell. For example, the range of system memory addresses may be a page of system memory addresses corresponding to a page of memory including the given memory cell (and, thus, the page of system memory addresses includes the system memory address of the memory cell).

The repair controller circuitry 720 of the illustrated example determines whether to invoke the memory repair circuitry 130 to repair a row of memory including a memory cell associated with a reported error. In the illustrated example, the repair controller circuitry 720 determines whether to invoke the memory repair circuitry 130 based on the type and/or severity of the error associated with the memory cell. In some examples, the repair controller circuitry 720 invokes the memory repair circuitry 130 for a given row of memory if the type of error associated with a memory cell included in that row is an uncorrectable error. In some examples, the repair controller circuitry 720 invokes the memory repair circuitry 130 for a given row of memory after the error count associated with that row is outside an error limit or satisfies (e.g., is greater than, is greater than or equal to, etc.) an error limit threshold, which indicates high error severity for that row of memory.

In some examples, the repair controller circuitry 720 causes the error handler circuitry 705 to translate the device address of a memory cell associated with an error to the corresponding system address of the memory cell after a repair of the row of memory including that memory cell fails or is unsuccessful (e.g., because the memory repair circuitry 130 has no PPR resources available to replace that row of memory). In some such examples, the repair controller circuitry 720 then causes the memory preservation circuitry 715 to isolate the system address of the memory cell (which isolates the memory cell itself) by reserving (e.g., marking) the system memory address of the memory as unusable in the memory map 725, or by reserving a range (e.g., page) of system memory addresses as unusable in the memory map 725, with the range (e.g., page) of system addresses including the system memory address of the memory cell.

The memory map 725 of the illustrated example identifies the system addresses that are accessible by the processor 110 and, more generally, the system 100. The memory map 725 can be implemented by any type(s) and/or number(s) of data structures, memory, storage, registers, etc. The memory map 725 also stores information that specifies access characteristics associated with the system addresses.

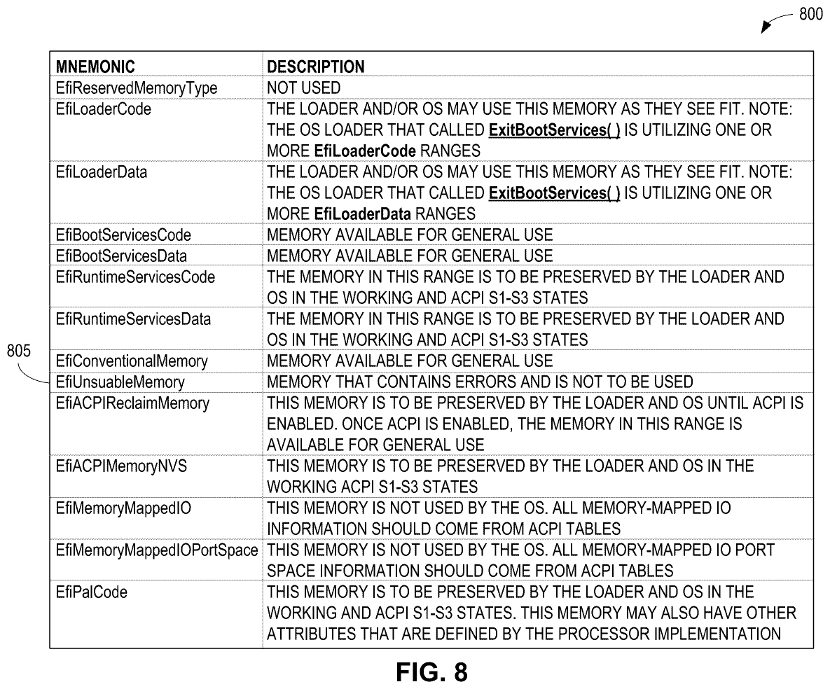

In some examples, the processor 110 (e.g., the BIOS of the processor 110) uses unified extensible firmware interface (UEFI) services to specify the access characteristics of respective system addresses (or ranges/pages of system addresses) in the memory map 725. In some such examples, the memory preservation circuitry 715 also uses one or more of the UEFI services to isolate memory of the memory subsystem 115 by reserving the system address(es) of the memory as unusable. FIG. 8 illustrates example UEFI information items 800 that can be used to specify access characteristics of respective system addresses in the memory map 725. In some examples, and as disclosed in further detail below, the memory preservation circuitry 715 uses the UEFI information item EfiUnusableMemory (labeled with reference numeral 805 in FIG. 8) to reserve a system memory address (or a range/page of system memory addresses) as unusable to isolate those system address(es) and associated memory cell(s) from the processor 110 and, more generally, the system 100.

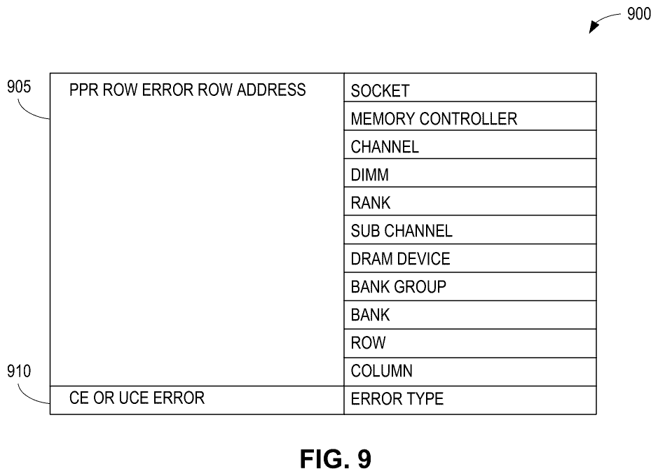

Returning to FIG. 7, the error handler circuitry 705 accesses detected memory cell errors reported by the memory subsystem 115, as described above. FIG. 9 illustrates an example memory error report 900 provided by the memory subsystem 115 to the error handler circuitry 705 to identify a given memory cell for which an error has been detected. The memory error report 900 of the illustrated example includes an example memory device address section 905 and an example error type section 910. The memory device address section 905 of the illustrated example specifies the device address of the memory cell exhibiting the error. For example, the memory device address section 905 specifies the device address in the form <Socket, Memory Controller, Channel, DIMM, Rank, Sub-Channel, DRAM device, Bank Group, Bank, Row, Column>. However, in other examples, the memory device address section 905 may specify the device address in another format. In the illustrated example, the error type section 910 specifies that type of error detected for the given memory cell. For example, the error type section 910 may specify whether the error is a correctable error or an uncorrectable error.

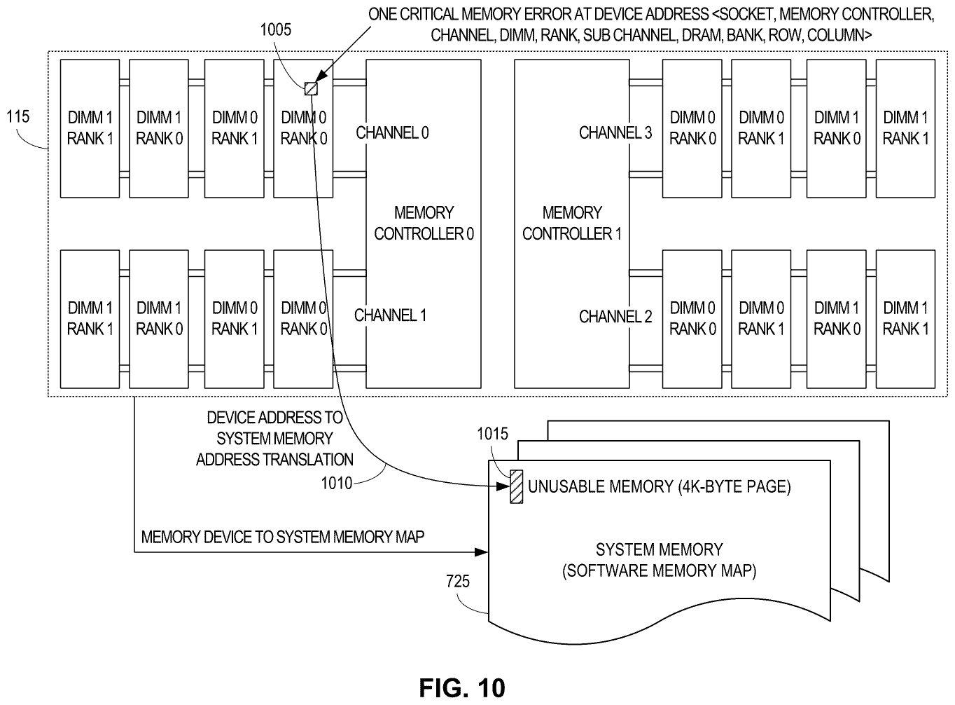

FIG. 10 illustrates an example operation 1000 of the memory isolation circuitry 105 of FIGS. 1 and/or 7 to perform memory cell isolation in the system 100. In the example operation 1000, the AMT or RAS feature of the memory subsystem 115 detects an error associated with an example memory cell 1005 and reports it to the error handler circuitry 705 using the memory error report 900. Thus, the error handler circuitry 705 obtains the device address for the failing memory cell 1005 (e.g., in the format <Socket, Memory Controller, Channel, DIMM, Rank, Sub-Channel, DRAM device, Bank Group, Bank, Row, Column>) and the error type, such as correctable or uncorrectable. In some examples, the error handler circuitry 705 saves the device address and error type of the memory cell 1005 in a non-volatile UEFI memory and causes the processor 110 to reboot.

During reboot, the error handler circuitry 705 extracts the device address of the failing memory cell 1005 from non-volatile UEFI variable and translates the device addresses into the corresponding system address of the memory cell 1005 (represented by reference numeral 1010 in FIG. 10). In some examples, the error handler circuitry 705 performs such address translation by (i) translating the device address elements <DIMM, Rank, Sub Channel, DRAM Device, Bank, Row, Column> into a channel address, and then (ii) translating the channel address to the system address by inserting the device address elements <Socket, Memory Controller, Channel> into proper locations of the system address bits based on information programmed by the BIOS into one or more reverse address translation registers of the processor 110.

Next, the memory preservation circuitry 715 uses the UEFI service EFI_BOOT_SERVICES.AllocatePages( ) to mark a memory page 1015 including the failing system address as EfiUnusableMemory in the memory map 725 according to Table 1.

TABLE 1

| | |
|---|---|
| typedef | |
| EFI_STATUS | |
| (EFIAPI *EFI_ALLOCATE_PAGES) ( | |
| IN EFI_ALLOCATE_TYPE | Type, |
| IN EFI_MEMORY_TYPE | MemoryType, |
| IN UINTN | Pages, |
| IN OUT EFI_PHYSICAL_ADDRESS | *Memory |
| ); | |

With reference to Table 1, in some examples, the memory preservation circuitry 715 assigns Enum item “AllocateAddress” (0x2) to the input parameter “Type” of Table 1, which indicates this service call is to allocate pages at a specified address. In some examples, the memory preservation circuitry 715 then assigns Enum item “EfiUnusableMemory” (0x8) to the input parameter “MemoryType” of Table1, which indicates that the allocated pages contain errors and are to be marked in the memory map 725 as unusable. In some examples, the memory preservation circuitry 715 then assigns the value 0x1 to input parameter “Pages” of Table 1, which indicates that this service call is to allocate one (1) page of memory (e.g., 4 KB). Finally, in some examples, the memory preservation circuitry 715 assigns the failing system memory address to input parameter “Memory” of Table 1, which indicates that the allocated pages shall start with the failing system memory address. If the service call EFI_BOOT_SERVICES.AllocatePageso returns EFI_SUCCESS, the failing memory address is successfully isolated.

Based on the foregoing description, the memory isolation circuitry 105 of FIGS. 1 and/or 7 may provide several beneficial features to the system 100. For example, in systems with no PPR resources and no ECC features available for memory repairing and error correction, the memory isolation circuitry 105 prevents an entire DDR rank from being disabled. Rather, the memory isolation circuitry 105 can translate the failing memory cell's physical device address to a corresponding system memory address and isolate the failing system memory address with an unusable memory type in the memory map 725, thereby avoiding a system crash. The failing DDR rank is kept alive, and the isolated memory could be small, such as 4 Kbyte page. Also, if a page on one memory rank is disabled on a memory channel, other channels do not need to disable the same page.

As another example, the memory isolation circuitry 105 can provide a technical solution that optimizes PPR resource usage based on the whether the detected memory error is correctable or uncorrectable, and based on an accumulated correctable error count. In this way, the memory isolation circuitry 105 avoids causing PPR resources to be exhausted by early correctable errors, which would leave no PPR resources available to repair later critical uncorrectable errors.

As yet another example, when correctable errors are detected for memory cells in rows of memory, the memory isolation circuitry 105 can record the correctable error count of each failing row. Then, in some examples, if the accumulated correctable error count for a given memory row is less than an error limit or other threshold, the health condition of that memory row may be deemed acceptable and PPR is not triggered or otherwise initiated for that row. Instead, the memory isolation circuitry 105 mark the failing row as unusable memory in the memory map to isolate it from the system to improve system memory stability. However, in some examples, if the accumulated correctable error count number for a given memory row is equal or greater than the error limit or other threshold, that row may be deemed unhealthy and the memory isolation circuitry 105 triggers or otherwise initiates PPR to repair the failing row to solve the accumulated correctable errors in that row. Also, in some examples, if the accumulated correctable error count number for a given memory row is equal or greater than the error limit or other threshold, but there are no PPR resources available for repairing memory row, the memory isolation circuitry 105 may translate the failing device address to the corresponding system memory address and mark the failing system memory address as unusable memory in the memory map, thereby isolating the failing row from the system and improving system memory stability.

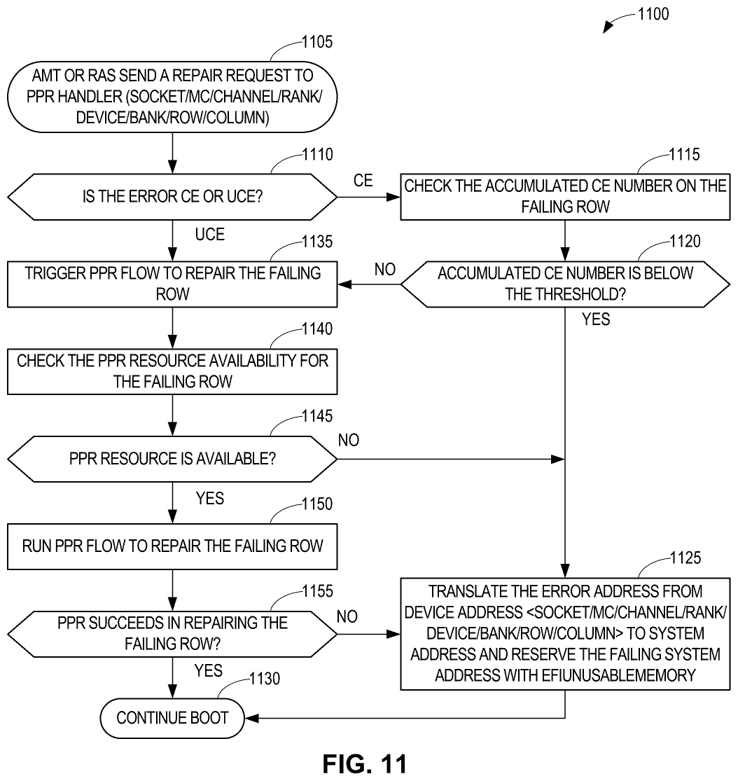

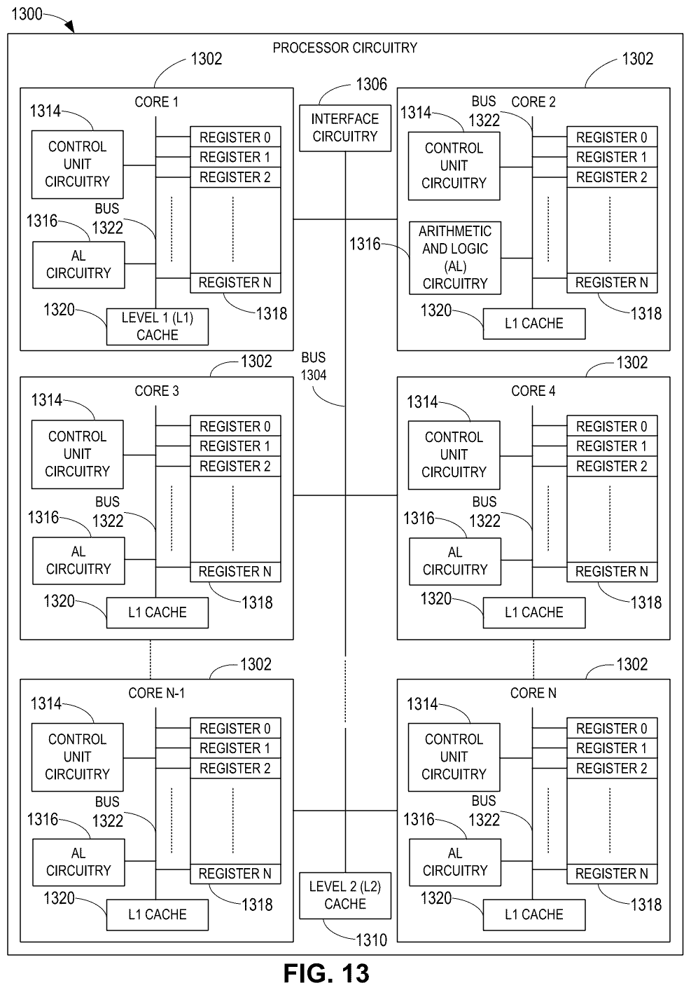

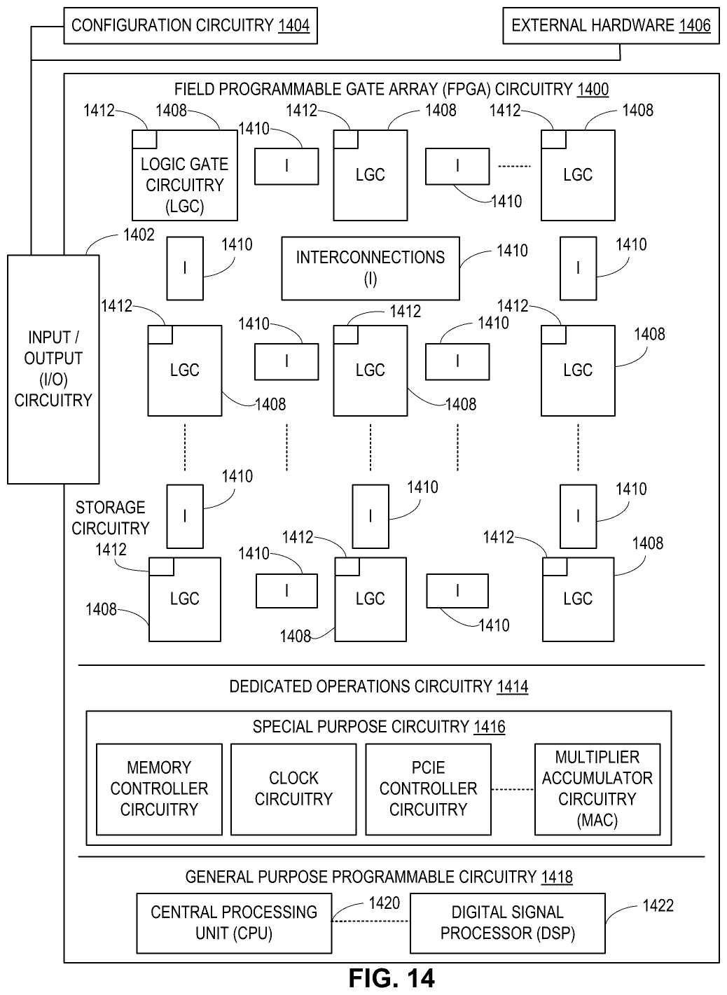

In some examples, the memory isolation circuitry 105 includes means for error handling. For example, the means for error handling may be implemented by the error handler circuitry 705. In some examples, the error handler circuitry 705 may be instantiated by programmable circuitry such as the example programmable circuitry 1212 of FIG. 12. For instance, the error handler circuitry 705 may be instantiated by the example microprocessor 1300 of FIG. 13 executing machine executable instructions such as those implemented by at least blocks 1105, 1110 and 1125 of FIG. 11. In some examples, the error handler circuitry 705 may be instantiated by hardware logic circuitry, which may be implemented by an ASIC, XPU, or the FPGA circuitry 1400 of FIG. 14 configured and/or structured to perform operations corresponding to the machine readable instructions. Additionally or alternatively, the error handler circuitry 705 may be instantiated by any other combination of hardware, software, and/or firmware. For example, the error handler circuitry 705 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In some examples, the memory isolation circuitry 105 includes means for error counting. For example, the means for error counting may be implemented by the error count circuitry 710. In some examples, the error count circuitry 710 may be instantiated by programmable circuitry such as the example programmable circuitry 1212 of FIG. 12. For instance, the error count circuitry 710 may be instantiated by the example microprocessor 1300 of FIG. 13 executing machine executable instructions such as those implemented by at least blocks 1115 and 1120 of FIG. 11. In some examples, the error count circuitry 710 may be instantiated by hardware logic circuitry, which may be implemented by an ASIC, XPU, or the FPGA circuitry 1400 of FIG. 14 configured and/or structured to perform operations corresponding to the machine readable instructions. Additionally or alternatively, the error count circuitry 710 may be instantiated by any other combination of hardware, software, and/or firmware. For example, the error count circuitry 710 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In some examples, the memory isolation circuitry 105 includes means for memory preservation. For example, the means for memory preservation may be implemented by the memory preservation circuitry 715. In some examples, the memory preservation circuitry 715 may be instantiated by programmable circuitry such as the example programmable circuitry 1212 of FIG. 12. For instance, the memory preservation circuitry 715 may be instantiated by the example microprocessor 1300 of FIG. 13 executing machine executable instructions such as those implemented by at least block 1125 of FIG. 11. In some examples, the memory preservation circuitry 715 may be instantiated by hardware logic circuitry, which may be implemented by an ASIC, XPU, or the FPGA circuitry 1400 of FIG. 14 configured and/or structured to perform operations corresponding to the machine readable instructions. Additionally or alternatively, the memory preservation circuitry 715 may be instantiated by any other combination of hardware, software, and/or firmware. For example, the memory preservation circuitry 715 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In some examples, the memory isolation circuitry 105 includes means for controlling memory repair. For example, the means for controlling memory repair may be implemented by the repair controller circuitry 720. In some examples, the repair controller circuitry 720 may be instantiated by programmable circuitry such as the example programmable circuitry 1212 of FIG. 12. For instance, the repair controller circuitry 720 may be instantiated by the example microprocessor 1300 of FIG. 13 executing machine executable instructions such as those implemented by at least blocks 1135-1155 of FIG. 11. In some examples, the repair controller circuitry 720 may be instantiated by hardware logic circuitry, which may be implemented by an ASIC, XPU, or the FPGA circuitry 1400 of FIG. 14 configured and/or structured to perform operations corresponding to the machine readable instructions. Additionally or alternatively, the repair controller circuitry 720 may be instantiated by any other combination of hardware, software, and/or firmware. For example, the repair controller circuitry 720 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

While an example manner of implementing the memory isolation circuitry 105 of FIG. 1 is illustrated in FIG. 7, one or more of the elements, processes, and/or devices illustrated in FIG. 7 may be combined, divided, re-arranged, omitted, eliminated, and/or implemented in any other way. Further, the example error handler circuitry 705, the example error count circuitry 710, the example memory preservation circuitry 715, the example repair controller circuitry 720, the example memory map 725, and/or, more generally, the example memory isolation circuitry 105 of FIG. 7, may be implemented by hardware alone or by hardware in combination with software and/or firmware. Thus, for example, any of the example error handler circuitry 705, the example error count circuitry 710, the example memory preservation circuitry 715, the example repair controller circuitry 720, the example memory map 725, and/or, more generally, the example memory isolation circuitry 105, could be implemented by programmable circuitry in combination with machine readable instructions (e.g., firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), and/or field programmable logic device(s) (FPLD(s)) such as FPGAs. Further still, the example memory isolation circuitry 105 of FIG. 7 may include one or more elements, processes, and/or devices in addition to, or instead of, those illustrated in FIG. 7, and/or may include more than one of any or all of the illustrated elements, processes and devices.

A flowchart representative of example machine readable instructions, which may be executed by programmable circuitry to implement and/or instantiate the memory isolation circuitry 105 of FIG. 7 and/or representative of example operations which may be performed by programmable circuitry to implement and/or instantiate the memory isolation circuitry 105 of FIG. 7, is shown in FIG. 11. The machine readable instructions may be one or more executable programs or portion(s) of one or more executable programs for execution by programmable circuitry such as the programmable circuitry 1212 shown in the example processor platform 1200 discussed below in connection with FIG. 12 and/or may be one or more function(s) or portion(s) of functions to be performed by the example programmable circuitry (e.g., an FPGA) discussed below in connection with FIGS. 13 and/or 14. In some examples, the machine readable instructions cause an operation, a task, etc., to be carried out and/or performed in an automated manner in the real world. As used herein, “automated” means without human involvement.

The program may be embodied in instructions (e.g., software and/or firmware) stored on one or more non-transitory computer readable and/or machine readable storage medium such as cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), and/or any other storage device or storage disk. The instructions of the non-transitory computer readable and/or machine readable medium may program and/or be executed by programmable circuitry located in one or more hardware devices, but the entire program and/or parts thereof could alternatively be executed and/or instantiated by one or more hardware devices other than the programmable circuitry and/or embodied in dedicated hardware. The machine readable instructions may be distributed across multiple hardware devices and/or executed by two or more hardware devices (e.g., a server and a client hardware device). For example, the client hardware device may be implemented by an endpoint client hardware device (e.g., a hardware device associated with a human and/or machine user) or an intermediate client hardware device gateway (e.g., a radio access network (RAN)) that may facilitate communication between a server and an endpoint client hardware device. Similarly, the non-transitory computer readable storage medium may include one or more mediums. Further, although the example program is described with reference to the flowchart(s) illustrated in FIG. 11, many other methods of implementing the example memory isolation circuitry 105 may alternatively be used. For example, the order of execution of the blocks of the flowchart(s) may be changed, and/or some of the blocks described may be changed, eliminated, or combined. Additionally or alternatively, any or all of the blocks of the flow chart may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware. The programmable circuitry may be distributed in different network locations and/or local to one or more hardware devices (e.g., a single-core processor (e.g., a single core CPU), a multi-core processor (e.g., a multi-core CPU, an XPU, etc.)). For example, the programmable circuitry may be a CPU and/or an FPGA located in the same package (e.g., the same integrated circuit (IC) package or in two or more separate housings), one or more processors in a single machine, multiple processors distributed across multiple servers of a server rack, multiple processors distributed across one or more server racks, etc., and/or any combination(s) thereof.

The machine readable instructions described herein may be stored in one or more of a compressed format, an encrypted format, a fragmented format, a compiled format, an executable format, a packaged format, etc. Machine readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, and/or produce machine executable instructions. For example, the machine readable instructions may be fragmented and stored on one or more storage devices, disks and/or computing devices (e.g., servers) located at the same or different locations of a network or collection of networks (e.g., in the cloud, in edge devices, etc.). The machine readable instructions may require one or more of installation, modification, adaptation, updating, combining, supplementing, configuring, decryption, decompression, unpacking, distribution, reassignment, compilation, etc., in order to make them directly readable, interpretable, and/or executable by a computing device and/or other machine. For example, the machine readable instructions may be stored in multiple parts, which are individually compressed, encrypted, and/or stored on separate computing devices, wherein the parts when decrypted, decompressed, and/or combined form a set of computer-executable and/or machine executable instructions that implement one or more functions and/or operations that may together form a program such as that described herein.

In another example, the machine readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine readable instructions may need to be configured (e.g., settings stored, data input, network addresses recorded, etc.) before the machine readable instructions and/or the corresponding program(s) can be executed in whole or in part. Thus, machine readable, computer readable and/or machine readable media, as used herein, may include instructions and/or program(s) regardless of the particular format or state of the machine readable instructions and/or program(s).

The machine readable instructions described herein can be represented by any past, present, or future instruction language, scripting language, programming language, etc. For example, the machine readable instructions may be represented using any of the following languages: C, C++, Java, C#, Perl, Python, JavaScript, HyperText Markup Language (HTML), Structured Query Language (SQL), Swift, etc.

As mentioned above, the example operations of FIG. 11 may be implemented using executable instructions (e.g., computer readable and/or machine readable instructions) stored on one or more non-transitory computer readable and/or machine readable media. As used herein, the terms non-transitory computer readable medium, non-transitory computer readable storage medium, non-transitory machine readable medium, and/or non-transitory machine readable storage medium are expressly defined to include any type of computer readable storage device and/or storage disk and to exclude propagating signals and to exclude transmission media. Examples of such non-transitory computer readable medium, non-transitory computer readable storage medium, non-transitory machine readable medium, and/or non-transitory machine readable storage medium include optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms “non-transitory computer readable storage device” and “non-transitory machine readable storage device” are defined to include any physical (mechanical, magnetic and/or electrical) hardware to retain information for a time period, but to exclude propagating signals and to exclude transmission media. Examples of non-transitory computer readable storage devices and/or non-transitory machine readable storage devices include random access memory of any type, read only memory of any type, solid state memory, flash memory, optical discs, magnetic disks, disk drives, and/or redundant array of independent disks (RAID) systems. As used herein, the term “device” refers to physical structure such as mechanical and/or electrical equipment, hardware, and/or circuitry that may or may not be configured by computer readable instructions, machine readable instructions, etc., and/or manufactured to execute computer-readable instructions, machine-readable instructions, etc.

FIG. 11 is a flowchart representative of example machine readable instructions and/or example operations 1100 that may be executed, instantiated, and/or performed by programmable circuitry to implement the memory isolation circuitry 105 of FIG. 7. The example machine-readable instructions and/or the example operations 1100 of FIG. 11 begin at block 1105, at which the AMT or RAS feature of the memory subsystem 115 detects an error associated with a memory cell and reports it to the error handler circuitry 705 of the memory isolation circuitry 105 (e.g., using the memory error report 900), as described above. At block 1110, the memory isolation circuitry 105 determines whether the error is a correctable error or an uncorrectable error. If the error is correctable (corresponding to the CE output of block 1110), then at block 1115 the error count circuitry 710 of the memory isolation circuitry 105 increments an error count (e.g., a correctable error count) associated with the memory row including the failing memory cell and checks the accumulated value of the error count, as described above. If the error count is within an error limit (e.g., below an error limit threshold) (corresponding to the Yes output of block 1120), then at block 1125 the error handler circuitry 705 translates the device address of the failing memory cell to a system memory address, and the memory preservation circuitry 715 of the memory isolation circuitry 105 isolates the system memory address (e.g., by reserving a page of system memory addresses including that system memory address as unusable), as described above. Then, at block 1130, the processor 110 of the system 100 continues to boot.

However, if the error is uncorrectable (corresponding to the UCE output of block 1110), or the error count (e.g., a correctable error count) associated with the memory row including the failing memory cell is outside the error limit (e.g., at or above the error limit threshold) (corresponding to the No output of block 1120), then at block 1135 the repair controller circuitry 720 of the memory isolation circuitry 105 triggers the PPR feature (e.g., implemented by the memory repair circuitry 130) to repair the failing memory row. In the illustrated example, at block 1140 the repair controller circuitry 720 determines whether PPR resources (e.g., reserved/redundant memory rows) are available to repair the memory row. If PPR resources are not available (corresponding to the No output of block 1145), then at block 1125 the error handler circuitry 705 and the memory preservation circuitry 715 isolate the failing memory address, as described above. Then, at block 1130, the processor 110 of the system 100 continues to boot.

However, if PPR resources are available (corresponding to the Yes output of block 1145), then at block 1150 the repair controller circuitry 720 causes the PPR feature to be performed to repair the failing memory row. If the repair is not successful (corresponding to the No output of block 1150), then at block 1125 the error handler circuitry 705 and the memory preservation circuitry 715 isolate the failing memory address, as described above. Then, at block 1130, the processor 110 of the system 100 continues to boot. However, if the repair is successful (corresponding to the Yes output of block 1150), the memory row is repaired, and at block 1130 the processor 110 of the system 100 continues to boot.

FIG. 12 is a block diagram of an example programmable circuitry platform 1200 structured to execute and/or instantiate the example machine-readable instructions and/or the example operations of FIG. 11 to implement the memory isolation circuitry 105 of FIG. 7. The programmable circuitry platform 1200 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a DVD player, a CD player, a digital video recorder, a Blu-ray player, a gaming console, a personal video recorder, a set top box, a headset (e.g., an augmented reality (AR) headset, a virtual reality (VR) headset, etc.) or other wearable device, or any other type of computing and/or electronic device.

The programmable circuitry platform 1200 of the illustrated example includes programmable circuitry 1212. The programmable circuitry 1212 of the illustrated example is hardware. For example, the programmable circuitry 1212 can be implemented by one or more integrated circuits, logic circuits, FPGAs, microprocessors, CPUs, GPUs, DSPs, and/or microcontrollers from any desired family or manufacturer. The programmable circuitry 1212 may be implemented by one or more semiconductor based (e.g., silicon based) devices. In this example, the programmable circuitry 1212 implements the example error handler circuitry 705, the example error count circuitry 710, the example memory preservation circuitry 715, the example repair controller circuitry 720, the example memory map 725 and/or, more generally, the memory isolation circuitry 105.

The programmable circuitry 1212 of the illustrated example includes a local memory 1213 (e.g., a cache, registers, etc.). The programmable circuitry 1212 of the illustrated example is in communication with main memory 1214, 1216, which includes a volatile memory 1214 and a non-volatile memory 1216, by a bus 1218. The volatile memory 1214 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 1216 may be implemented by flash memory and/or any other desired type of memory device. Access to the main memory 1214, 1216 of the illustrated example is controlled by a memory controller 1217. In some examples, the memory controller 1217 may be implemented by one or more integrated circuits, logic circuits, microcontrollers from any desired family or manufacturer, or any other type of circuitry to manage the flow of data going to and from the main memory 1214, 1216.

The programmable circuitry platform 1200 of the illustrated example also includes interface circuitry 1220. The interface circuitry 1220 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface.

In the illustrated example, one or more input devices 1222 are connected to the interface circuitry 1220. The input device(s) 1222 permit(s) a user (e.g., a human user, a machine user, etc.) to enter data and/or commands into the programmable circuitry 1212. The input device(s) 1222 can be implemented by, for example, an audio sensor, a microphone, a camera (still or video), a keyboard, a button, a mouse, a touchscreen, a trackpad, a trackball, an isopoint device, and/or a voice recognition system.

One or more output devices 1224 are also connected to the interface circuitry 1220 of the illustrated example. The output device(s) 1224 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 1220 of the illustrated example, thus, typically includes a graphics driver card, a graphics driver chip, and/or graphics processor circuitry such as a GPU.

The interface circuitry 1220 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 1226. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 1200 of the illustrated example also includes one or more mass storage discs or devices 1228 to store firmware, software, and/or data. Examples of such mass storage discs or devices 1228 include magnetic storage devices (e.g., floppy disk, drives, HDDs, etc.), optical storage devices (e.g., Blu-ray disks, CDs, DVDs, etc.), RAID systems, and/or solid-state storage discs or devices such as flash memory devices and/or SSDs.

The machine readable instructions 1232, which may be implemented by the machine readable instructions of FIG. 11, may be stored in the mass storage device 1228, in the volatile memory 1214, in the non-volatile memory 1216, and/or on at least one non-transitory computer readable storage medium such as a CD or DVD which may be removable.

FIG. 13 is a block diagram of an example implementation of the programmable circuitry 1212 of FIG. 12. In this example, the programmable circuitry 1212 of FIG. 12 is implemented by a microprocessor 1300. For example, the microprocessor 1300 may be a general-purpose microprocessor (e.g., general-purpose microprocessor circuitry). The microprocessor 1300 executes some or all of the machine-readable instructions of the flowchart of FIG. 11 to effectively instantiate the circuitry of FIG. 7 as logic circuits to perform operations corresponding to those machine readable instructions. In some such examples, the circuitry of FIG. 7 is instantiated by the hardware circuits of the microprocessor 1300 in combination with the machine-readable instructions. For example, the microprocessor 1300 may be implemented by multi-core hardware circuitry such as a CPU, a DSP, a GPU, an XPU, etc. Although it may include any number of example cores 1302 (e.g., 1 core), the microprocessor 1300 of this example is a multi-core semiconductor device including N cores. The cores 1302 of the microprocessor 1300 may operate independently or may cooperate to execute machine readable instructions. For example, machine code corresponding to a firmware program, an embedded software program, or a software program may be executed by one of the cores 1302 or may be executed by multiple ones of the cores 1302 at the same or different times. In some examples, the machine code corresponding to the firmware program, the embedded software program, or the software program is split into threads and executed in parallel by two or more of the cores 1302. The software program may correspond to a portion or all of the machine readable instructions and/or operations represented by the flowchart of FIG. 11.

The cores 1302 may communicate by a first example bus 1304. In some examples, the first bus 1304 may be implemented by a communication bus to effectuate communication associated with one(s) of the cores 1302. For example, the first bus 1304 may be implemented by at least one of an Inter-Integrated Circuit (I2C) bus, a Serial Peripheral Interface (SPI) bus, a PCI bus, or a PCIe bus. Additionally or alternatively, the first bus 1304 may be implemented by any other type of computing or electrical bus. The cores 1302 may obtain data, instructions, and/or signals from one or more external devices by example interface circuitry 1306. The cores 1302 may output data, instructions, and/or signals to the one or more external devices by the interface circuitry 1306. Although the cores 1302 of this example include example local memory 1320 (e.g., Level 1 (L1) cache that may be split into an L1 data cache and an L1 instruction cache), the microprocessor 1300 also includes example shared memory 1310 that may be shared by the cores (e.g., Level 2 (L2 cache)) for high-speed access to data and/or instructions. Data and/or instructions may be transferred (e.g., shared) by writing to and/or reading from the shared memory 1310. The local memory 1320 of each of the cores 1302 and the shared memory 1310 may be part of a hierarchy of storage devices including multiple levels of cache memory and the main memory (e.g., the main memory 1214, 1216 of FIG. 12). Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 1302 may be referred to as a CPU, DSP, GPU, etc., or any other type of hardware circuitry. Each core 1302 includes control unit circuitry 1314, arithmetic and logic (AL) circuitry (sometimes referred to as an ALU) 1316, a plurality of registers 1318, the local memory 1320, and a second example bus 1322. Other structures may be present. For example, each core 1302 may include vector unit circuitry, single instruction multiple data (SIMD) unit circuitry, load/store unit (LSU) circuitry, branch/jump unit circuitry, floating-point unit (FPU) circuitry, etc. The control unit circuitry 1314 includes semiconductor-based circuits structured to control (e.g., coordinate) data movement within the corresponding core 1302. The AL circuitry 1316 includes semiconductor-based circuits structured to perform one or more mathematic and/or logic operations on the data within the corresponding core 1302. The AL circuitry 1316 of some examples performs integer-based operations. In other examples, the AL circuitry 1316 also performs floating-point operations. In yet other examples, the AL circuitry 1316 may include first AL circuitry that performs integer-based operations and second AL circuitry that performs floating-point operations. In some examples, the AL circuitry 1316 may be referred to as an Arithmetic Logic Unit (ALU).

The registers 1318 are semiconductor-based structures to store data and/or instructions such as results of one or more of the operations performed by the AL circuitry 1316 of the corresponding core 1302. For example, the registers 1318 may include vector register(s), SIMD register(s), general-purpose register(s), flag register(s), segment register(s), machine-specific register(s), instruction pointer register(s), control register(s), debug register(s), memory management register(s), machine check register(s), etc. The registers 1318 may be arranged in a bank as shown in FIG. 13. Alternatively, the registers 1318 may be organized in any other arrangement, format, or structure, such as by being distributed throughout the core 1302 to shorten access time. The second bus 1322 may be implemented by at least one of an I2C bus, a SPI bus, a PCI bus, or a PCIe bus.

Each core 1302 and/or, more generally, the microprocessor 1300 may include additional and/or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) and/or other circuitry may be present. The microprocessor 1300 is a semiconductor device fabricated to include many transistors interconnected to implement the structures described above in one or more integrated circuits (ICs) contained in one or more packages.

The microprocessor 1300 may include and/or cooperate with one or more accelerators (e.g., acceleration circuitry, hardware accelerators, etc.). In some examples, accelerators are implemented by logic circuitry to perform certain tasks more quickly and/or efficiently than can be done by a general-purpose processor. Examples of accelerators include ASICs and FPGAs such as those discussed herein. A GPU, DSP and/or other programmable device can also be an accelerator. Accelerators may be on-board the microprocessor 1300, in the same chip package as the microprocessor 1300 and/or in one or more separate packages from the microprocessor 1300.

FIG. 14 is a block diagram of another example implementation of the programmable circuitry 1212 of FIG. 12. In this example, the programmable circuitry 1212 is implemented by FPGA circuitry 1400. For example, the FPGA circuitry 1400 may be implemented by an FPGA. The FPGA circuitry 1400 can be used, for example, to perform operations that could otherwise be performed by the example microprocessor 1300 of FIG. 13 executing corresponding machine readable instructions. However, once configured, the FPGA circuitry 1400 instantiates the operations and/or functions corresponding to the machine readable instructions in hardware and, thus, can often execute the operations/functions faster than they could be performed by a general-purpose microprocessor executing the corresponding software.

More specifically, in contrast to the microprocessor 1300 of FIG. 13 described above (which is a general purpose device that may be programmed to execute some or all of the machine readable instructions represented by the flowchart(s) of FIG. 11 but whose interconnections and logic circuitry are fixed once fabricated), the FPGA circuitry 1400 of the example of FIG. 14 includes interconnections and logic circuitry that may be configured, structured, programmed, and/or interconnected in different ways after fabrication to instantiate, for example, some or all of the operations/functions corresponding to the machine readable instructions represented by the flowchart(s) of FIG. 11. In particular, the FPGA circuitry 1400 may be thought of as an array of logic gates, interconnections, and switches. The switches can be programmed to change how the logic gates are interconnected by the interconnections, effectively forming one or more dedicated logic circuits (unless and until the FPGA circuitry 1400 is reprogrammed). The configured logic circuits enable the logic gates to cooperate in different ways to perform different operations on data received by input circuitry. Those operations may correspond to some or all of the instructions (e.g., the software and/or firmware) represented by the flowchart(s) of FIG. 11. As such, the FPGA circuitry 1400 may be configured and/or structured to effectively instantiate some or all of the operations/functions corresponding to the machine readable instructions of the flowchart(s) of FIG. 11 as dedicated logic circuits to perform the operations/functions corresponding to those software instructions in a dedicated manner analogous to an ASIC. Therefore, the FPGA circuitry 1400 may perform the operations/functions corresponding to the some or all of the machine readable instructions of FIG. 11 faster than the general-purpose microprocessor can execute the same.

In the example of FIG. 14, the FPGA circuitry 1400 is configured and/or structured in response to being programmed (and/or reprogrammed one or more times) based on a binary file. In some examples, the binary file may be compiled and/or generated based on instructions in a hardware description language (HDL) such as Lucid, Very High Speed Integrated Circuits (VHSIC) Hardware Description Language (VHDL), or Verilog. For example, a user (e.g., a human user, a machine user, etc.) may write code or a program corresponding to one or more operations/functions in an HDL; the code/program may be translated into a low-level language as needed; and the code/program (e.g., the code/program in the low-level language) may be converted (e.g., by a compiler, a software application, etc.) into the binary file. In some examples, the FPGA circuitry 1400 of FIG. 14 may access and/or load the binary file to cause the FPGA circuitry 1400 of FIG. 14 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 1400 of FIG. 14 to cause configuration and/or structuring of the FPGA circuitry 1400 of FIG. 14, or portion(s) thereof.

In some examples, the binary file is compiled, generated, transformed, and/or otherwise output from a uniform software platform utilized to program FPGAs. For example, the uniform software platform may translate first instructions (e.g., code or a program) that correspond to one or more operations/functions in a high-level language (e.g., C, C++, Python, etc.) into second instructions that correspond to the one or more operations/functions in an HDL. In some such examples, the binary file is compiled, generated, and/or otherwise output from the uniform software platform based on the second instructions. In some examples, the FPGA circuitry 1400 of FIG. 14 may access and/or load the binary file to cause the FPGA circuitry 1400 of FIG. 14 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 1400 of FIG. 14 to cause configuration and/or structuring of the FPGA circuitry 1400 of FIG. 14, or portion(s) thereof.

The FPGA circuitry 1400 of FIG. 14, includes example input/output (I/O) circuitry 1402 to obtain and/or output data to/from example configuration circuitry 1404 and/or external hardware 1406. For example, the configuration circuitry 1404 may be implemented by interface circuitry that may obtain a binary file, which may be implemented by a bit stream, data, and/or machine-readable instructions, to configure the FPGA circuitry 1400, or portion(s) thereof. In some such examples, the configuration circuitry 1404 may obtain the binary file from a user, a machine (e.g., hardware circuitry (e.g., programmable or dedicated circuitry) that may implement an Artificial Intelligence/Machine Learning (AI/ML) model to generate the binary file), etc., and/or any combination(s) thereof). In some examples, the external hardware 1406 may be implemented by external hardware circuitry. For example, the external hardware 1406 may be implemented by the microprocessor 1300 of FIG. 13.

The FPGA circuitry 1400 also includes an array of example logic gate circuitry 1408, a plurality of example configurable interconnections 1410, and example storage circuitry 1412. The logic gate circuitry 1408 and the configurable interconnections 1410 are configurable to instantiate one or more operations/functions that may correspond to at least some of the machine readable instructions of FIG. 11 and/or other desired operations. The logic gate circuitry 1408 shown in FIG. 14 is fabricated in blocks or groups. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 1408 to enable configuration of the electrical structures and/or the logic gates to form circuits to perform desired operations/functions. The logic gate circuitry 1408 may include other electrical structures such as look-up tables (LUTs), registers (e.g., flip-flops or latches), multiplexers, etc.

The configurable interconnections 1410 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 1408 to program desired logic circuits.

The storage circuitry 1412 of the illustrated example is structured to store result(s) of the one or more of the operations performed by corresponding logic gates. The storage circuitry 1412 may be implemented by registers or the like. In the illustrated example, the storage circuitry 1412 is distributed amongst the logic gate circuitry 1408 to facilitate access and increase execution speed.

The example FPGA circuitry 1400 of FIG. 14 also includes example dedicated operations circuitry 1414. In this example, the dedicated operations circuitry 1414 includes special purpose circuitry 1416 that may be invoked to implement commonly used functions to avoid the need to program those functions in the field. Examples of such special purpose circuitry 1416 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 1400 may also include example general purpose programmable circuitry 1418 such as an example CPU 1420 and/or an example DSP 1422. Other general purpose programmable circuitry 1418 may additionally or alternatively be present such as a GPU, an XPU, etc., that can be programmed to perform other operations.

Although FIGS. 13 and 14 illustrate two example implementations of the programmable circuitry 1212 of FIG. 12, many other approaches are contemplated. For example, FPGA circuitry may include an on-board CPU, such as one or more of the example CPU 1420 of FIG. 13. Therefore, the programmable circuitry 1212 of FIG. 12 may additionally be implemented by combining at least the example microprocessor 1300 of FIG. 13 and the example FPGA circuitry 1400 of FIG. 14. In some such hybrid examples, one or more cores 1302 of FIG. 13 may execute a first portion of the machine readable instructions represented by the flowchart(s) of FIG. 11 to perform first operation(s)/function(s), the FPGA circuitry 1400 of FIG. 14 may be configured and/or structured to perform second operation(s)/function(s) corresponding to a second portion of the machine readable instructions represented by the flowcharts of FIG. 11, and/or an ASIC may be configured and/or structured to perform third operation(s)/function(s) corresponding to a third portion of the machine readable instructions represented by the flowchart of FIG. 11.

It should be understood that some or all of the circuitry of FIG. 7 may, thus, be instantiated at the same or different times. For example, same and/or different portion(s) of the microprocessor 1300 of FIG. 13 may be programmed to execute portion(s) of machine-readable instructions at the same and/or different times. In some examples, same and/or different portion(s) of the FPGA circuitry 1400 of FIG. 14 may be configured and/or structured to perform operations/functions corresponding to portion(s) of machine-readable instructions at the same and/or different times.

In some examples, some or all of the circuitry of FIG. 7 may be instantiated, for example, in one or more threads executing concurrently and/or in series. For example, the microprocessor 1300 of FIG. 13 may execute machine readable instructions in one or more threads executing concurrently and/or in series. In some examples, the FPGA circuitry 1400 of FIG. 14 may be configured and/or structured to carry out operations/functions concurrently and/or in series. Moreover, in some examples, some or all of the circuitry of FIG. 7 may be implemented within one or more virtual machines and/or containers executing on the microprocessor 1300 of FIG. 13.

In some examples, the programmable circuitry 1212 of FIG. 12 may be in one or more packages. For example, the microprocessor 1300 of FIG. 13 and/or the FPGA circuitry 1400 of FIG. 14 may be in one or more packages. In some examples, an XPU may be implemented by the programmable circuitry 1212 of FIG. 12, which may be in one or more packages. For example, the XPU may include a CPU (e.g., the microprocessor 1300 of FIG. 13, the CPU 1420 of FIG. 14, etc.) in one package, a DSP (e.g., the DSP 1422 of FIG. 14) in another package, a GPU in yet another package, and an FPGA (e.g., the FPGA circuitry 1400 of FIG. 14) in still yet another package.

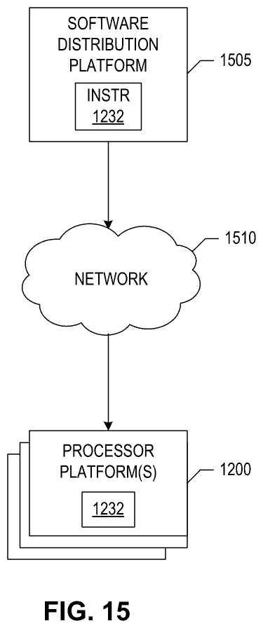

A block diagram illustrating an example software distribution platform 1505 to distribute software such as the example machine readable instructions 1232 of FIG. 12 to other hardware devices (e.g., hardware devices owned and/or operated by third parties from the owner and/or operator of the software distribution platform) is illustrated in FIG. 15. The example software distribution platform 1505 may be implemented by any computer server, data facility, cloud service, etc., capable of storing and transmitting software to other computing devices. The third parties may be customers of the entity owning and/or operating the software distribution platform 1505. For example, the entity that owns and/or operates the software distribution platform 1505 may be a developer, a seller, and/or a licensor of software such as the example machine readable instructions 1232 of FIG. 12. The third parties may be consumers, users, retailers, OEMs, etc., who purchase and/or license the software for use and/or re-sale and/or sub-licensing. In the illustrated example, the software distribution platform 1505 includes one or more servers and one or more storage devices. The storage devices store the machine readable instructions 1232, which may correspond to the example machine readable instructions of FIG. 11, as described above. The one or more servers of the example software distribution platform 1505 are in communication with an example network 1510, which may correspond to any one or more of the Internet and/or any of the example networks described above. In some examples, the one or more servers are responsive to requests to transmit the software to a requesting party as part of a commercial transaction. Payment for the delivery, sale, and/or license of the software may be handled by the one or more servers of the software distribution platform and/or by a third party payment entity. The servers enable purchasers and/or licensors to download the machine readable instructions 1232 from the software distribution platform 1505. For example, the software, which may correspond to the example machine readable instructions of FIG. 11, may be downloaded to the example programmable circuitry platform 1200, which is to execute the machine readable instructions 1232 to implement the memory isolation circuitry 105. In some examples, one or more servers of the software distribution platform 1505 periodically offer, transmit, and/or force updates to the software (e.g., the example machine readable instructions 1232 of FIG. 12) to ensure improvements, patches, updates, etc., are distributed and applied to the software at the end user devices. Although referred to as software above, the distributed “software” could alternatively be firmware.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real-world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time+1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

In this disclosure, some examples of memory, memory subsystems, device memory addresses and system memory addresses have been used to describe the example memory cell isolation techniques disclosed herein. However, memory cell isolation in accordance with teachings of this disclosure is not limited to those examples of memory, memory subsystems, device memory addresses and system memory addresses. On the contrary, memory cell isolation techniques implemented in accordance with teachings of this disclosure can be employed with any type of device and system memory address scheme that provides a device memory address capable of accessing a physical memory location (e.g., a memory cell) and a corresponding system memory address that provides at least one level of indirection from the device memory address (e.g., via a memory map and/or other data structure). Furthermore, memory cell isolation techniques implemented in accordance with teachings of this disclosure can be employed with any type of memory, memory subsystems, etc., that are accessible by a processor and/or other circuit/device via system memory addresses that provide at least one level of indirection (e.g., via a memory map and/or other data structure) from corresponding device memory addresses that are capable of accessing physical memory locations.

From the foregoing, it will be appreciated that example systems, apparatus, articles of manufacture, and methods have been disclosed that perform memory cell isolation to improve system reliability. Disclosed systems, apparatus, articles of manufacture, and methods improve the efficiency of using a computing device by isolating system memory addresses associated with memory cell errors, thereby preventing system access to those failed memory cells. As a result, systems employing such memory isolation techniques can keep a memory rank or other memory grouping enabled even in the face of errors associated with memory cells in that rank/grouping. Disclosed systems, apparatus, articles of manufacture, and methods are accordingly directed to one or more improvement(s) in the operation of a machine such as a computer or other electronic and/or mechanical device.

Further examples and combinations thereof include the following. Example 1 includes at least one non-transitory computer readable medium comprising computer readable instructions to cause at least one processor circuit to at least increment an error count after detection of an error associated with a memory cell, and isolate a system memory address of the memory cell based on the error count.

Example 2 includes the at least one non-transitory computer readable medium of example 1, wherein the computer readable instructions are to cause one or more of the at least one processor circuit to translate a device address of the memory cell to the system memory address after a determination that the error count does not satisfy a threshold.

Example 3 includes the at least one non-transitory computer readable medium of example 1 or example 2, wherein the computer readable instructions are to cause one or more of the at least one processor circuit to isolate the system memory address by reserving a page of system memory addresses including the system memory address as unusable.

Example 4 includes the at least one non-transitory computer readable medium of any one of examples 1 to 3, wherein the computer readable instructions are to cause one or more of the at least one processor circuit to invoke repair circuitry to repair a row of memory including the memory cell after the error count satisfies a threshold.

Example 5 includes the at least one non-transitory computer readable medium of example 4, wherein the computer readable instructions are to cause one or more of the at least one processor circuit to translate a device address of the memory cell to the system memory address after the repair of the row of memory is unsuccessful, and isolate the system memory address by reserving a range of system memory addresses including the system memory address as unusable.

Example 6 includes the at least one non-transitory computer readable medium of example 5, wherein the computer readable instructions are to cause one or more of the at least one processor circuit to reserve the range of system memory addresses as unusable by marking a page of system memory addresses including the system memory address as unusable in a memory map.

Example 7 includes the at least one non-transitory computer readable medium of any one of examples 1 to 6, wherein the error is a correctable error.

Example 8 includes the at least one non-transitory computer readable medium of any one of examples 1 to 7, wherein the error is a first correctable error, the memory cell is a first memory cell included in a first row of memory, and the computer readable instructions are to cause one or more of the at least one processor circuit to initiate repair of a second row of memory after detection of an uncorrectable error associated with a second memory cell included in the second row of memory.

Example 9 includes the at least one non-transitory computer readable medium of example 8, wherein the system memory address is a first system memory address, and the computer readable instructions are to cause one or more of the at least one processor circuit to translate a device address of the second memory cell to a second system memory address after the repair of the second row of memory is unsuccessful, and isolate a range of system memory addresses including the second system memory address.

Example 10 includes the at least one non-transitory computer readable medium of example 8, wherein the computer readable instructions are to cause one or more of the at least one processor circuit to initiate the repair of the second row of memory by invoking repair circuitry, the repair circuitry to attempt to replace the second row of memory with a third row of memory.

Example 11 includes an apparatus comprising machine readable instructions, and at least one processor circuit to be programmed based on the machine readable instructions to increment an error count associated with a row of memory after detection of an error associated with a memory cell included in the row of memory, and reserve, based on the error count, a range of system memory addresses as unusable to cause the range of system memory address to be isolated, the range of system memory addresses including a system memory address of the memory cell.

Example 12 includes the apparatus of example 11, wherein the range of system memory addresses corresponds to a page of system memory addresses.

Example 13 includes the apparatus of example 11 or example 12, wherein one or more of the at least one processor circuit is to translate a device address of the memory cell to the system memory address after a determination that the error count is within an error limit.

Example 14 includes the apparatus of example 13, wherein one or more of the at least one processor circuit is to invoke repair circuitry to repair a row of memory after a determination that the error count is not within the error limit, the row of memory including the memory cell, and reserve the range of system memory addresses as unusable to cause the range of system memory address to be isolated after the repair of the row of memory is unsuccessful.

Example 15 includes the apparatus of any one of examples 11 to 14, wherein the error is a correctable error.

Example 16 includes a method comprising incrementing an error count associated with a row of memory after detection of an error associated with a memory cell included in the row of memory, determining that the error count is within an error limit, and reserving, by executing an instruction with at least one processor circuit, a range of system memory addresses as unusable to cause the row of memory to be isolated, the range of system memory addresses including a system memory address or the memory cell.

Example 17 includes the method of example 16, wherein the range of system memory addresses corresponds to a page of system memory addresses.

Example 18 includes the method of example 17, wherein the reserving of the range of system memory addresses includes marking the page of the system memory addresses as unusable in a memory map.

Example 19 includes the method of any one of examples 16 to 18, wherein the reserving of the range of system memory addresses includes translating a device address of the memory cell to the system memory address.

Example 20 includes the method of any one of example 16 to 19, wherein the error is a first error, the memory cell is a first memory cell, the row of memory is a first row of memory, and including incrementing the error count after detection of a second error associated with a second memory cell included in the row of memory, determining that the error count is outside the error limit, initiating an attempt to replace the first row of memory with a second row of memory, and reserving the range of system memory addresses as unusable to cause the row of memory to be isolated after the attempt is unsuccessful.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. At least one non-transitory computer readable medium comprising computer readable instructions to cause at least one processor circuit to at least:
increment an error count after detection of an error associated with a memory cell; and
isolate a system memory address of the memory cell based on the error count.

2. The at least one non-transitory computer readable medium of claim 1, wherein the computer readable instructions are to cause one or more of the at least one processor circuit to translate a device address of the memory cell to the system memory address after a determination that the error count does not satisfy a threshold.

3. The at least one non-transitory computer readable medium of claim 1, wherein the computer readable instructions are to cause one or more of the at least one processor circuit to isolate the system memory address by reserving a page of system memory addresses including the system memory address as unusable.

4. The at least one non-transitory computer readable medium of claim 1, wherein the computer readable instructions are to cause one or more of the at least one processor circuit to invoke repair circuitry to repair a row of memory including the memory cell after the error count satisfies a threshold.

5. The at least one non-transitory computer readable medium of claim 4, wherein the computer readable instructions are to cause one or more of the at least one processor circuit to:
translate a device address of the memory cell to the system memory address after the repair of the row of memory is unsuccessful; and
isolate the system memory address by reserving a range of system memory addresses including the system memory address as unusable.

6. The at least one non-transitory computer readable medium of claim 5, wherein the computer readable instructions are to cause one or more of the at least one processor circuit to reserve the range of system memory addresses as unusable by marking a page of system memory addresses including the system memory address as unusable in a memory map.

7. The at least one non-transitory computer readable medium of claim 1, wherein the error is a correctable error.

8. The at least one non-transitory computer readable medium of claim 1, wherein the error is a first correctable error, the memory cell is a first memory cell included in a first row of memory, and the computer readable instructions are to cause one or more of the at least one processor circuit to initiate repair of a second row of memory after detection of an uncorrectable error associated with a second memory cell included in the second row of memory.

9. The at least one non-transitory computer readable medium of claim 8, wherein the system memory address is a first system memory address, and the computer readable instructions are to cause one or more of the at least one processor circuit to:
translate a device address of the second memory cell to a second system memory address after the repair of the second row of memory is unsuccessful; and
isolate a range of system memory addresses including the second system memory address.

10. The at least one non-transitory computer readable medium of claim 8, wherein the computer readable instructions are to cause one or more of the at least one processor circuit to initiate the repair of the second row of memory by invoking repair circuitry, the repair circuitry to attempt to replace the second row of memory with a third row of memory.

11. An apparatus comprising:
machine readable instructions; and
at least one processor circuit to be programmed based on the machine readable instructions to:
increment an error count associated with a row of memory after detection of an error associated with a memory cell included in the row of memory; and
reserve, based on the error count, a range of system memory addresses as unusable to cause the range of system memory address to be isolated, the range of system memory addresses including a system memory address of the memory cell.

12. The apparatus of claim 11, wherein the range of system memory addresses corresponds to a page of system memory addresses.

13. The apparatus of claim 11, wherein one or more of the at least one processor circuit is to translate a device address of the memory cell to the system memory address after a determination that the error count is within an error limit.

14. The apparatus of claim 13, wherein one or more of the at least one processor circuit is to:
invoke repair circuitry to repair a row of memory after a determination that the error count is not within the error limit, the row of memory including the memory cell; and
reserve the range of system memory addresses as unusable to cause the range of system memory address to be isolated after the repair of the row of memory is unsuccessful.

15. The apparatus of claim 11, wherein the error is a correctable error.

16. A method comprising:
incrementing an error count associated with a row of memory after detection of an error associated with a memory cell included in the row of memory;
determining that the error count is within an error limit; and
reserving, by executing an instruction with at least one processor circuit, a range of system memory addresses as unusable to cause the row of memory to be isolated, the range of system memory addresses including a system memory address or the memory cell.

17. The method of claim 16, wherein the range of system memory addresses corresponds to a page of system memory addresses.

18. The method of claim 17, wherein the reserving of the range of system memory addresses includes marking the page of the system memory addresses as unusable in a memory map.

19. The method of claim 16, wherein the reserving of the range of system memory addresses includes translating a device address of the memory cell to the system memory address.

20. The method of claim 16, wherein the error is a first error, the memory cell is a first memory cell, the row of memory is a first row of memory, and including:
incrementing the error count after detection of a second error associated with a second memory cell included in the row of memory;
determining that the error count is outside the error limit;
initiating an attempt to replace the first row of memory with a second row of memory; and
reserving the range of system memory addresses as unusable to cause the row of memory to be isolated after the attempt is unsuccessful.
